(19) United States
(12) Patent Application Publication
(10) Pub. No.: US 2022/0137755 A1
(43) Pub. Date: May 5, 2022

(54) ARRAY SUBSTRATE AND DISPLAY DEVICE

(71) Applicants: Beijing BOE Display Technology Co., Ltd., Beijing (CN); BOE Technology Group Co., Ltd., Beijing (CN)

(72) Inventors: Yi LIU, Beijing (CN); Shijun WANG, Beijing (CN); Wenkai MU, Beijing (CN); Bo FENG, Beijing (CN); Xiaoxiao CHEN, Beijing (CN); Yang WANG, Beijing (CN); Zhan WEI, Beijing (CN); Tengfei DING, Beijing (CN); Xinlan YANG, Beijing (CN); Xiaofeng YIN, Beijing (CN)

(21) Appl. No.: 17/258,148

(22) PCT Filed: Mar. 27, 2020
(86) PCT No.: PCT/CN2020/081868

§ 371 Date: Jan. 5, 2021

(51) Int. Cl. G06F 3/044; G06F 3/041

(52) U.S. Cl. CPC G06F 3/0446; G06F 3/04164; G06F 3/0443

(57) ABSTRACT

The present disclosure provides an array substrate and a display device. The array substrate comprises: a base substrate; a plurality of touch lines on the base substrate; and a touch electrode layer located on a side, facing away from the base substrate, of a layer where the touch lines are located. The touch electrode layer comprises a plurality of touch electrodes, and the touch electrodes are provided with hollowed-out areas at positions of the touch lines.

### CROSS REFERENCE TO RELATED DOCUMENTS

The present application is a national phase entry under 35 U.S.C. § 371 of International Application No. PCT/CN2020/081868, filed on Mar. 27, 2020.

### FIELD

The present disclosure relates to the field of display technology, in particular to an array substrate and a display device.

### BACKGROUND

Along with rapid development of the display technology, touch screen panels have gradually spread throughout people's lives. According to the principle of touch induction, existing touch screen panels include resistive touch screen panels, capacitive touch screen panels, surface infrared touch screen panels, etc. Capacitive touch screen panels are favored by more and more consumers due to its high light transmittance, wear resistance, resistance to change of ambient temperature, resistance to change of ambient humidity, long service life, and capability of realizing such advanced and complex functions as multi-touch.

### SUMMARY

Embodiments of the present disclosure provide an array substrate, including:

a base substrate;

a plurality of touch lines on the base substrate; and

a touch electrode layer located on a side, facing away from the base substrate, of a layer where the touch lines are located.

The touch electrode layer includes a plurality of touch electrodes, and the touch electrodes are provided with hollowed-out areas at positions of the touch lines.

Optionally, in the above array substrate provided in embodiments of the present disclosure, the touch electrodes each includes: a plurality of first touch electrodes, and a second touch electrode surrounding the first touch electrodes.

The second touch electrode is spaced and insulated from each of the first touch electrodes.

Optionally, in the above array substrate provided in embodiments of the present disclosure, the touch electrode layer further includes: a plurality of lap joint parts. The lap-joint parts are connected to the first touch electrodes or the second touch electrodes at two sides of the respective hollowed-out areas.

Optionally, the above array substrate provided in embodiments of the present disclosure further includes: a plurality of gate lines intersecting with the touch lines.

The lap-joint parts are arranged in a one-to-one correspondence manner at intersected positions between the touch lines and the gate lines.

Optionally, the above array substrate provided in embodiments of the present disclosure further includes: a plurality of data lines, intersecting with the gate lines and in the layer where the touch lines are located.

A hollowed-out area corresponding to each touch line is provided with a data line.

Optionally, in the above array substrate provided in embodiments of the present disclosure, the hollowed-out areas cover column gaps between columns of blue sub-pixel areas and columns of red sub-pixel areas defined by the gate lines and the data lines.

Optionally, in the above array substrate provided in embodiments of the present disclosure, in a same hollowed-out area, a touch lines is arranged between a data line and a column of a blue sub-pixel area.

Optionally, in the above array substrate provided in embodiments of the present disclosure, the touch lines each is provided with a wave-shaped structure, and the wave-shaped structure is composed of a plurality of arc segments, and line segments each connecting two adjacent arc segments.

Optionally, in the above array substrate provided in embodiments of the present disclosure, two arc segments located on two sides of a same gate line are in mirror symmetry with respect to the same gate line, and a line segment connecting the two arc segments is in mirror symmetry with respect to the same gate line.

Optionally, in the above array substrate provided in embodiments of the present disclosure, an extension direction of the touch electrodes at boundaries of two sides of the respective hollowed-out areas is parallel with an extension direction of the touch lines.

Optionally, in the above array substrate provided in embodiments of the present disclosure, the data lines are parallel with the touch lines.

Optionally, the above array substrate provided in embodiments of the present disclosure further includes a plurality of pixel electrodes located on a side, facing away from a layer where the data lines are located, of the touch electrode layer.

An extension direction of the pixel electrodes is parallel with an extension direction of the data lines which define sub-pixel areas where the pixel electrodes are located.

Optionally, the above array substrate provided in embodiments of the present disclosure further includes: a common electrode layer. The common electrode layer is multiplexed as the touch electrode layer.

Based on the same inventive concept, embodiments of the present disclosure further provide a display device, including the above array substrate.

### BRIEF DESCRIPTION OF THE DRAWINGS

FIG. 1 is a schematic structural diagram of an array substrate provided by an embodiment of the present disclosure;

FIG. 2 is an enlarged schematic structural diagram of a dashed box area in FIG. 1;

FIG. 3 is another schematic structural diagram of an array substrate provided by an embodiment of the present disclosure;

FIG. 4 is still another schematic structural diagram of an array substrate provided by an embodiment of the present disclosure.

### DETAILED DESCRIPTION OF THE EMBODIMENTS

In order to make the objectives, technical solutions and advantages of the embodiments of the present disclosure clearer, the technical solutions of the embodiments of the present disclosure are described clearly and completely in conjunction with the accompanying drawings of the embodiments of the present disclosure below. The thickness and shape of each film layer in the accompanying drawings do not reflect the true ratio, but merely schematically illustrate the present disclosure. Apparently, the described embodiments are part of the embodiments of the present disclosure, rather than all of the embodiments. Based on the described embodiments of the present disclosure, all other embodiments obtained by those of ordinary skill in the art without creative labor fall within the protection scope of the present disclosure.

Unless otherwise defined, the technical terms or scientific terms used herein shall have the usual meanings understood by those with ordinary skill in the field to which the present disclosure belongs. The “first”, “second” and similar words used in the specification and claims of the present disclosure do not indicate any order, quantity or importance, but are only used to distinguish different components. “Include” or “comprise” and other similar words mean that the element or item appearing before the word encompasses the element or item listed after the word and its equivalents, but does not exclude other elements or items. “Inner”, “outer”, “upper”, “lower” and so on are only used to indicate the relative position relationship. After the absolute position of the described object changes, the relative position relationship may also change accordingly.

In the related art, during a touch operation, a finger forms coupling capacitance between the surface of a touch screen panel and the ground, thereby increasing ground capacitance of a touch electrode and causing capacitance on a touch electrode layer to change. A touch detecting chip (IC) recognizes the change to determine the touch position and reacts, thereby recognizing a touch signal. However, in the related art, one touch line will generally be overlapped with a column of touch electrodes, and will be electrically connected with one touch electrode in the column of touch electrodes, to recognize the capacitance change of the touch electrode. Obviously, a coupling capacitance will exist between the touch line and other touch electrodes, other than the touch electrode electrically connected with the touch line, in the column, thereby influencing the touch accuracy.

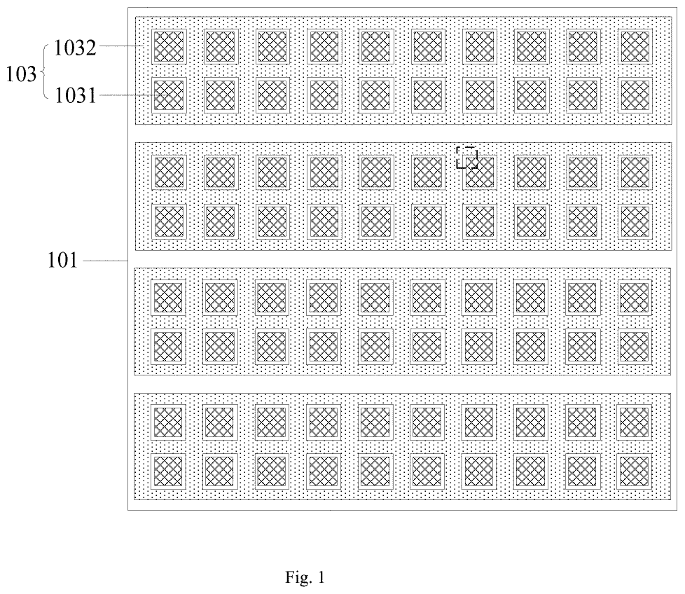

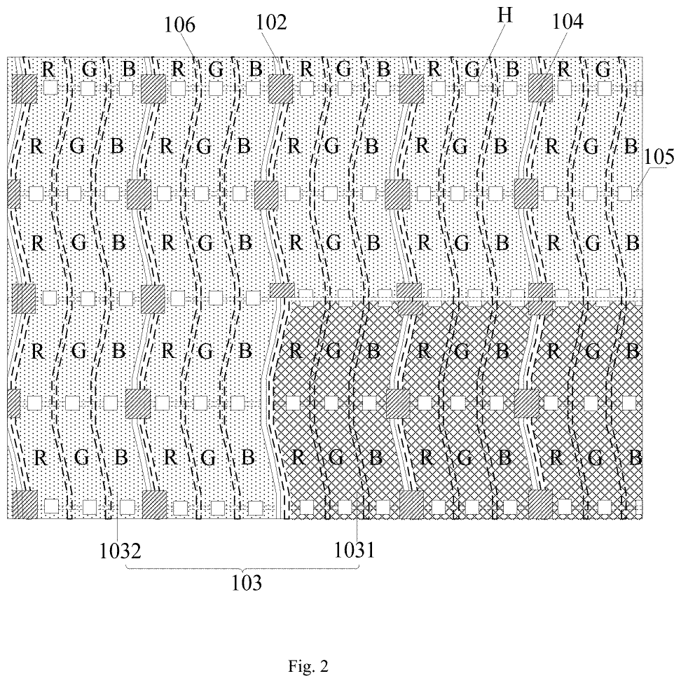

In view of the above-mentioned problems in the related art, some embodiments of the present disclosure provide an array substrate applicable to products of the low temperature poly-silicon (LTPS) process. Specifically, as shown in FIG. 1 and FIG. 2, the array substrate includes:

a base substrate 101;

a plurality of touch lines 102 on the base substrate 101; and

a touch electrode layer located on a side, facing away from the base substrate 101, of a layer where the touch lines 102 are located.

The touch electrode layer includes a plurality of touch electrodes 103, and the touch electrodes 103 is provided with hollowed-out areas at positions of the touch lines 102.

In the above array substrate provided in embodiments of the present disclosure, since the touch lines 102 are arranged in the hollowed-out areas of the touch electrodes 103, overlapping between the touch electrode layer and the touch line 102 is avoided, thereby reducing the coupling capacitance between the touch lines 102 and the touch electrode layer, reducing the signal to noise ratio, saving the power consumption, and improving the touch accuracy.

It should be noted that in the above-mentioned array substrate provided by the embodiments of the present disclosure, the base substrate 101 may be a flexible base substrate, such as polyvinyl ether phthalate, polyethylene naphthalate, polycarbonate, polyarylate, polyetherimide, polyether sulfone or polyimide and other plastic substrates with excellent heat resistance and durability; the base substrate 101 may also be a rigid base substrate, such as a glass substrate, which is not limited herein. Specifically, the touch lines 102 may be made of molybdenum, aluminum, silver, copper, titanium, platinum, tungsten, tantalum, tantalum nitride, alloys and combinations thereof, or other suitable materials, which are not limited herein.

In the related art, the touch function and the display function are performed in a time-sharing mode within a frame, resulting in insufficient pixel charging rate. Based on this, in order to improve the pixel charging rate, in the above-mentioned array substrate provided by the embodiments of the present disclosure, as shown in FIG. 1, each touch electrode 103 includes a plurality of first touch electrodes 1031, and a second touch electrode 1032 surrounding the first touch electrodes 1031; and the second touch electrode 1032 is spaced and insulated from each of the first touch electrodes 1031.

It should be noted that, as shown in FIG. 1, a second touch electrode 1032 extending along a row direction surrounds two rows of first touch electrodes 1031. During specific implementation, a second touch electrode 1032 extending along a row direction can surrounds one row or at least three rows of first touch electrodes 1031, which can be set specifically according to actually required touch density, and is not defined herein.

In addition, in some embodiments, the first touch electrodes 1031 are driving electrodes (Tx sensor), and the second touch electrodes 1032 are induction electrodes (Rx sensor). In some other embodiments, the first touch electrodes 1031 are induction electrodes, and the second touch electrodes 1032 are driving electrodes, which is not defined herein.

It can be seen from FIG. 1 that each first touch electrode 1031 and the corresponding second touch electrode 1032 form a concentric-square-shaped ring structure. In this way, the touch position can be recognized based on the principle of self-capacitance and the principle of mutual capacitance at the same time. In addition, the self-capacitance and mutual capacitance integrated technology can also realize the synchronization of the touch function and the display function, thereby increasing the pixel charging rate. Furthermore, the self-capacitance and mutual capacitance integrated technology further has the advantages of supporting active styli and waterproofing, and is suitable for the development of mobile products (e.g., mobile phones) that comply with the stylus protocol. Besides, it can be understood that in the case of the same product size, the number of self-capacitance and mutual capacitance integrated touch electrodes provided in the present disclosure is less than the number of touch electrodes based on single self-capacitance or single mutual capacitance, and therefore the number of touch channels can be reduced, and the narrow frame design is achieved.

Optionally, in the above array substrate provided in embodiments of the present disclosure, as shown in FIG. 2, the touch electrode layer further includes: a plurality of lap-joint parts 104. The lap-joint parts 104 are connected to the first touch electrodes 1031 or the second touch electrodes 1032 at two sides of the respective hollowed-out areas.

Since the interior of the same first touch electrode 1031 is disconnected due to the arrangement of the hollowed-out areas, the signal consistency on the same first touch electrode 1031 is ensured by arranging the lap-joint parts 104. Similarly, the interior of the same second touch electrode 1032 is disconnected due to the arrangement of the hollowed-out areas, and the signal consistency on the same second touch electrode 1032 is also ensured by arranging the lap-joint parts 104.

In addition, it can be understood that, the first touch electrodes 1031 and the second touch electrodes 1032 need to be insulated from each other. Therefore, no lap-joint part 104 needs to be arranged to connect the first touch electrodes 1031 and the second touch electrodes 1032 on two sides of the hollowed-out areas. In other words, gaps formed by the hollowed-out areas are reserved between the first touch electrodes 1031 and the second touch electrodes 1032 to ensure that there is no short between the first touch electrodes 1031 and the second touch electrodes 1032, so that signals of the first touch electrodes and the second touch electrodes do not interfere.

Optionally, as shown in FIG. 2, the above array substrate provided in embodiments of the present disclosure further includes a plurality of gate lines 105 intersecting with the touch lines 102. The lap-joint parts 104 are arranged in a one-to-one correspondence manner at intersected positions between the touch lines 102 and the gate lines 105.

Since coupling capacitance may exist between the lap-joint parts 104 and the touch lines 102 located in the hollowed-out areas to a certain extent, it is necessary to set the number and positions of the lap-joint parts 104 reasonably. The lap-joint parts 104 are arranged in a one-to-one correspondence manner at the intersected positions between the touch lines 102 and the gate lines 105, which not only ensures the signal uniformity on the first touch electrodes 1031 or the second touch electrodes 1032, but also avoids large coupling interference between the first lap-joint parts 104 and the touch lines 102 due to excessive lap joint parts 104.

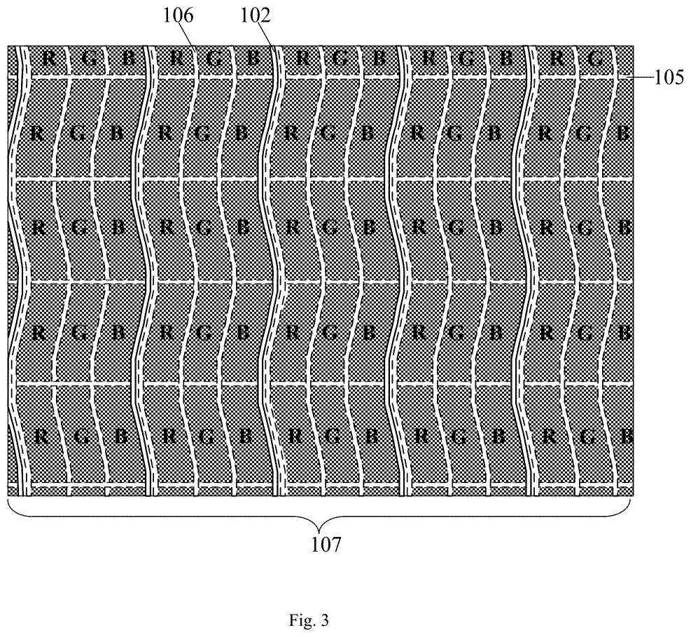

Optionally, as shown in FIG. 2 and FIG. 3, the above array substrate provided in embodiments of the present disclosure further includes: a plurality of data lines 106 intersecting with the gate line s105 and in the layer where the touch lines 102 are located.

A hollowed-out area corresponding to each touch line 102 is provided with a data line 106.

It should be noted that in the present disclosure, “same layer arrangement” refers to a layer structure formed by: forming film layers through the same film forming process for forming specific patterns, and then performing a single patterning process with the same mask plate on the film layers. That is, the single patterning process corresponds to one mask plate. A single patterning process may include multiple exposure, development or etching processes according to the differences of specific patterns, and the specific patterns in the formed layer structure may be continuous or discontinuous, and these specific patterns may also be at different heights or have different thicknesses. Therefore, the touch lines 102 and the data lines 106 are arranged in the same layer, the masking process can be reduced, and the production efficiency is improved.

Generally, since the touch density is less than the Pixels Per Inch (PPI), a touch electrode covers multiple sub-pixels, for example, a touch electrode covers M*N sub-pixels, M and N are integers larger than 1. On this basis, it should be understood that, the number of the data lines 106 is larger than the number of the touch lines 102.

Specifically, the data lines 106 and the gate lines 105 define multiple sub-pixel areas. As shown in FIG. 2 and FIG. 3, the sub-pixel areas include red sub-pixel areas R, green sub-pixel areas G and blue sub-pixel areas B. The color of the sub-pixel areas in the same column is the same, and “the red sub-pixel area R, the green sub-pixel area G and the blue sub-pixel area B” are cyclically arranged in a cycle in the row direction. The column of the red sub-pixel area R, the column of the green sub-pixel area G, and the column of the blue sub-pixel area B included in each cycle form a pixel column, and each column of sub-pixel areas corresponds to a data line 106. Of course, during specific implementation, to improve the display brightness, the sub-pixel areas defined by the data lines 106 and the gate lines 105 can further include a white sub-pixel area W. In addition, black matrixes can further be set in the areas corresponding to the row gaps and column gaps of the red sub-pixel areas R, the green sub-pixel areas G and the blue sub-pixel areas B. On the one hand, light crosstalk of adjacent sub-pixel areas can be prevented; on the other hand, the gate lines 105 at the row gaps and the data lines 106 and the touch lines 102 at the column gaps can be shielded by the black matrix, thereby preventing the touch line s102, the gate lines 105 and the data lines 106 from being visible by naked eyes, and improving the appearance experience of the product.

Specifically, in the above-mentioned array substrate provided by the embodiments of the present disclosure, the touch lines 102 include touch drive lines (Tx line) and touch induction lines (Rx line). Since the touch drive lines and the touch induction lines are parallel to the extension direction of the data lines 106, touch detecting chips may be arranged on the same side of the array substrate to realize single-side driving, and a narrow frame effect is achieved.

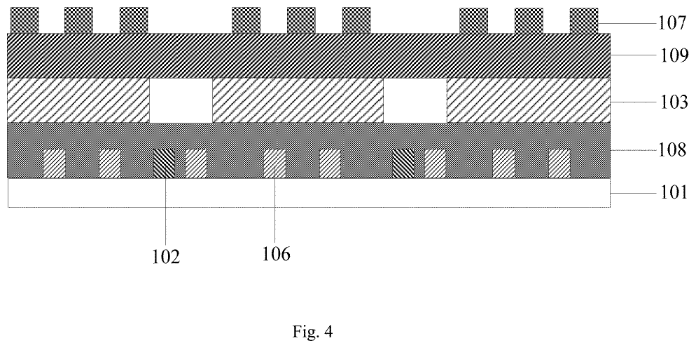

Optionally, in the above array substrate provided in embodiments of the present disclosure, as shown in FIG. 2 and FIG. 4, the hollowed-out areas cover column gaps between columns of the blue sub-pixel areas B and columns of the red sub-pixel areas R defined by the gate lines 105 and the data lines 106.

Specifically, the hollowed-out area can completely cover and is larger than the column gap between the column of the blue sub-pixel area B and the column of the red sub-pixel area R defined by the gate line 105 and the data line 106. In other words, an orthographic projection of the column gap between the column of the blue sub-pixel area B and the column of the red sub-pixel area R on the base substrate 101 is in the orthographic projection of the hollowed-out area. Alternatively, the hollowed-out areas can completely coincide with the gap columns between the columns of the blue sub-pixel areas B and the columns of the red sub-pixel areas R defined by the gate lines 105 and the data lines 106. That is to say, the shape and size of the orthographic projection of the column gap between the column of the blue sub-pixel area B and the column of the red sub-pixel area R on the base substrate 101 are completely the same as the shape and size of the orthographic projection of the hollowed-out area. In consideration of the condition that the touch electrode 103 is reused with the common electrode, the electric field intensity between the common electrode at two sides of the hollowed-out area and its opposite pixel electrode is defined by the opposite areas of the two. Therefore, to ensure the electric field strength between the common electrode and the pixel electrode, preferably, the hollowed-out area completely coincides with the column gap between the column in which the blue sub-pixel area B is located and the column in which the red sub-pixel area R is located defined by the gate line 105 and the data line 106.

Optionally, in the above array substrate provided in embodiments of the present disclosure, as shown in FIG. 3, in the same hollowed-out area, the touch line 102 is arranged between the data line 106 and the column of the blue sub-pixel area B.

Since the sensitivity of human eyes to blue is weaker than the sensitivity of human eyes to red and green, therefore, when the touch line 102 is set to close to the column of the blue sub-pixel area B, the viewing experience will not be influenced.

Optionally, in the above array substrate provided in embodiments of the present disclosure, as shown in FIG. 2 and FIG. 3, the touch line 102 is provided with a wave-shaped structure, and the wave-shaped structure is composed of a plurality of arc segments and line segments each connecting two adjacent arc segments. Of course, during specific implementation, the wave-shaped structure can also be only composed of a plurality of arc segments.

In the related art, linear touch lines 102 extending in a direction perpendicular to the gate lines 105 are prone to cause light interference with regular shapes (such as black matrix patterns) in a touch screen panel, causing moire phenomenon, which affects the display effect. Based on this, by arranging the touch line 102 as a wave-shaped structure, moire patterns of the touch line 102 caused by light interference due to regular patterns can be reduced, and the visibility of the moire patterns on the surface of the touch screen panel can be eliminated, and the display quality is improved.

Optionally, in the above array substrate provided in embodiments of the present disclosure, as shown in FIG. 2 and FIG. 3, two arc segments located on two sides of the same gate line 105 are in mirror symmetry with respect to the gate line 105, and the line segment which connects the two arc segments is in mirror symmetry with respect to the gate line 105.

The line segment which connects the two arc segments in the touch line 102 is set to be in mirror symmetry with respect to the gate line 105, such that the hollowed-out area covering the touch line 102 has a rectangular shape in the partial hollowed-out area at the intersected position between the hollowed-out area and the gate line 105. Moreover, it can be understood that, when the extension direction of the touch electrode 103 at the boundaries at two sides of the hollowed-out area is parallel with the extension direction of the touch line 102, the partial hollowed-out area at the intersected position between the hollowed-out area and the gate line 105 is a rectangle. In addition, it can be known from the above description that, the lap-joint part 104 is arranged in the intersected position between the gate line 105 and the touch line 102, to connect the first touch electrodes 1031 or the second touch electrodes 1032 at two sides of the hollowed-out area. Therefore, the lap-joint part 104 needs to cover the above partial hollowed-out area, when the above partial hollowed-out area is a rectangular shape, the manufacturing of the lap-joint part 104 is facilitated, and the production efficiency is improved.

Optionally, in the above array substrate provided in embodiments of the present disclosure, the data line 106 is parallel with the touch line 102. Through setting the data line 106 to be a wave-shaped structure which is the same as the touch line 102, the Moire patterns caused by the data line 106 due to light interference caused by regular graphs can be reduced, thereby eliminating the visibility of the Moire patterns on the surface of the touch screen panel, and improving the display quality.

Optionally, as shown in FIG. 3 and FIG. 4, the above array substrate provided in embodiments of the present disclosure further includes: a plurality of pixel electrodes 107 arranged on a side, facing away from the layer in which data lines 106 are located, of the touch electrode layer (that is, the layer in which the touch electrode 103 is located).

The extension direction of the pixel electrode 107 is parallel with the extension direction of the data line 106 which defines the sub-pixel area in which the pixel electrode is located.

Since the data lines 106 at two sides of the same gate line 105 are in mirror symmetry with respect to the gate line 105, therefore, when the extension direction of the pixel electrode 108 is parallel with the extension direction of the data line 106 which defines the sub-pixel area in which the pixel electrode is located, the two pixel electrodes 108 at two sides of the same gate line 102 have two domains (that is, 2 Pixel 2 Domain) which are in mirror symmetry with respect to the gate line 105. The pixel electrode 108 is designed to have a certain pre-inclined angle, and can achieve a favorable effect in light transmittance and light efficiency.

It should be noted that, to facilitating distinguishment, both FIG. 2 and FIG. 3 show the positions of the touch lines 102 with full lines, and show the positions of the data lines 106 with dotted lines. Moreover, in FIG. 2, the white areas represent hollowed-out areas of the touch electrodes 103, and the pattern filling areas represent the touch electrodes 103. In FIG. 3, the white areas represent the row gaps between the rows in which the pixel electrodes 107 are located and the column gaps between the columns in which the pixel electrodes 107 are located, and the pattern filling areas represent the pixel electrodes 107.

Optionally, the above array substrate provided in embodiments of the present disclosure further includes: a common electrode layer, and the common electrode layer is multiplexed as a touch electrode layer.

When the touch electrode layer is multiplexed as a common electrode layer, the thickness of the touch screen panel can be reduced, thereby realizing lightweight design. Optionally, the first touch electrodes 1031, the second touch electrodes 1032 and the lap-joint parts 104 contained in the touch electrode layer can be in the same layer and made of the same material. Moreover, when the first touch electrodes 1031, the second touch electrodes 1032 and the lap joint parts 104 are in the same layer and made of the same material, the first touch electrodes 1031, the second touch electrodes 1032 and the lap joint parts 104 can be made simultaneously, to simplify the manufacturing process of the array substrate. Optionally, the first touch electrodes 1031, the second touch electrodes 1032 and the lap-joint parts 104 are all made of transparent conducting materials. Exemplarily, the materials of the first touch electrodes 1031, the second touch electrodes 1032 and the lap joint parts 104 comprise such materials with favorable light transmittance and electrical conductivity as indium tin oxide or indium zinc oxide.

Optionally, as shown in FIG. 4, the above array substrate provided in embodiments of the present disclosure generally can further include a layer 108 in which the transistors are located. When the touch electrode layer (that is, the layer in which the touch electrodes 103 are located) is multiplexed as a common electrode layer, an insulating layer 109 is arranged between the pixel electrodes 107 and the common electrode layer. The layer 108 in which the transistors are located includes: a gate, a gate insulating layer, an active layer, an interlayer dielectric layer and a source/drain layer. Specifically, a flattening layer (not shown in the figure) will also be generally arranged between the layer 108 in which the transistors are arranged and the common electrode layer. Moreover, when the common electrode layer is arranged between the layer 108 in which the transistors are arranged and the pixel electrode 107, the pixel electrodes 107 can be electrically connected with the transistors through via holes H on the common electrode layer, as shown in FIG. 2. Further, to simplify the process, two via holes H at two sides of a gate line 105 can be designed to be integrated, as shown in FIG. 2. Specifically, various shapes can be designed for the via hole H, for example, any regular or irregular shape like a circle, a triangle, a rectangle, a rhombus, a trapezoid, a five-pointed star or a regular polygon, which is not defined herein.

Based on the same inventive concept, embodiments of the present disclosure further provide a display device including the above-mentioned array substrate provided in embodiments of the present disclosure. The display device may be: a liquid crystal display panel, a mobile phone, a tablet computer, a television, a monitor, a notebook computer, a digital photo frame, a navigator, a smart watch, a fitness wristband, a personal digital assistant and any other products or components with display functions. Other indispensable parts of the display device should be understood by those of ordinary skill in the art, are not described in detail herein, and should not be used as a limitation on the present disclosure. In addition, since the principle of solving the problem of the display device is similar to the principle of solving the problem of the above-mentioned display panel, the implementation of the display device may refer to the embodiments of the above-mentioned display panel, and is not described in detail herein.

The embodiments of the present disclosure provide the above array substrate and display device. The array substrate includes a base substrate; a plurality of touch lines on the base substrate; and a touch electrode layer on a side, facing away from the base substrate, of a layer where the touch lines are located. The touch electrode layer includes a plurality of touch electrodes, and the touch electrodes are provided with hollowed-out areas at positions of the touch lines. Each touch line is arranged in the hollowed-out area of the touch electrode, thereby avoiding overlapping between the touch electrode layer and each touch line, reducing the coupling capacitance between the touch line and the touch electrode layer, and improving the touch accuracy.

Evidently, those skilled in the art can make various modifications and variations to the embodiments of the present invention without departing from the spirit and scope of the present invention. Accordingly, the present invention is also intended to encompass these modifications and variations thereto so long as the modifications and variations come into the scope of the claims appended to the invention and their equivalents.

1. An array substrate, comprising:
a base substrate;
a plurality of touch lines on the base substrate; and
a touch electrode layer located on a side, facing away from the base substrate, of a layer where the touch lines are located;
wherein the touch electrode layer comprises a plurality of touch electrodes, and the touch electrodes are provided with hollowed-out areas at positions of the touch lines.

2. The array substrate of claim 1, wherein the touch electrodes each comprises:
a plurality of first touch electrodes; and
a second touch electrode surrounding the first touch electrodes;
wherein the second touch electrode is spaced and insulated from each of the first touch electrodes.

3. The array substrate of claim 2, wherein the touch electrode layer further comprises:
a plurality of lap-joint parts;
wherein the lap-joint parts are connected to the first touch electrodes or the second touch electrodes on two sides of the respective hollowed-out areas.

4. The array substrate of claim 3, further comprising:
a plurality of gate lines intersecting with the touch lines;
wherein the lap-joint parts are arranged in a one-to-one correspondence manner at intersected positions between the touch lines and the gate lines.

5. The array substrate of claim 4, further comprising:
a plurality of data lines, intersecting with the gate lines and in the layer where the touch lines are located;
wherein a hollowed-out area corresponding to each touch line is provided with a data line.

6. The array substrate of claim 5, wherein the hollowed-out areas cover column gaps between columns of blue sub-pixel areas and columns of red sub-pixel areas defined by the gate lines and the data lines.

7. The array substrate of claim 6, wherein in a same hollowed-out area, a touch line is arranged between a data line and a column of a blue sub-pixel area.

8. The array substrate of claim 5, wherein the touch lines each is provided with a wave-shaped structure, and the wave-shaped structure is composed of a plurality of arc segments, and line segments each connecting two adjacent arc segments.

9. The array substrate of claim 8, wherein two arc segments located on two sides of a same gate line are in mirror symmetry with respect to the same gate line, and a line segment connecting the two arc segments is in mirror symmetry with respect to the same gate line.

10. The array substrate of claim 8, wherein an extension direction of the touch electrodes at boundaries of two sides of the respective hollowed-out areas is parallel with an extension direction of the touch lines.

11. The array substrate of claim 8, wherein the data lines are parallel with the touch lines.

12. The array substrate of claim 11, further comprising:
a plurality of pixel electrodes located on a side, facing away from a layer where the data lines are located, of the touch electrode layer;
wherein an extension direction of the pixel electrodes is parallel with an extension direction of the data lines which define sub-pixel areas where the pixel electrodes are located.

13. The array substrate of claim 1, further comprising:
a common electrode layer;
wherein the common electrode layer is multiplexed as the touch electrode layer.

14. A display device, comprising: the array substrate of claim 1.

15. The array substrate of claim 1, wherein the touch lines each is provided with a wave-shaped structure, and the wave-shaped structure is composed of a plurality of arc segments, and line segments each connecting two adjacent arc segments.

16. The array substrate of claim 15, wherein an extension direction of the touch electrodes at boundaries of two sides of the respective hollowed-out areas is parallel with an extension direction of the touch lines.

17. The array substrate of claim 4, wherein the touch lines each is provided with a wave-shaped structure, and the wave-shaped structure is composed of a plurality of arc segments, and line segments each connecting two adjacent arc segments.

18. The array substrate of claim 17, wherein two arc segments located on two sides of a same gate line are in mirror symmetry with respect to the same gate line, and a line segment connecting the two arc segments is in mirror symmetry with respect to the same gate line.

19. The array substrate of claim 17, wherein an extension direction of the touch electrodes at boundaries of two sides of the respective hollowed-out areas is parallel with an extension direction of the touch lines.
